(19) United States
(12) Patent Application Publication
(10) Pub. No.: US 2008/0301537 A1
(43) Pub. Date: Dec. 4, 2008

(54) Packet transmission device and packet transmission method

(75) Inventor: Hiroshi Isono, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kanagawa (JP)

(21) Appl. No.: 12/153,974

(22) Filed: May 28, 2008

(30) Foreign Application Priority Data
May 31, 2007 (JP) 145432/2007

(51) Int. Cl. H03M 13/05; G06F 11/07

(52) U.S. Cl. 714/807; 714/E11.024

(57) ABSTRACT

Aiming to shorten the transmission operation, the present invention provides an apparatus including a memory, a checksum calculation circuit, and a transmission device. The memory stores data of a packet to be transmitted. The checksum calculation section reads data sets corresponding to all the packet fragments except for that having a checksum storage area, sequentially and cumulatively adds the data sets to obtain a checksum value, thereafter reads a data set corresponding to the fragment having the checksum storage area therein from the memory, and adds the read data to the checksum value to obtain a final checksum value. The transmission section sequentially transmits the fragments once the individual fragments are used for the checksum calculation in the checksum calculation section, and, thereafter, transmits the fragment which is read from the memory and has the checksum storage area including the final checksum value therein.

### BACKGROUND OF THE INVENTION

1. Field of the Invention

The present invention relates to a packet transmission device and a packet transmission method, and, in particular, relates to a technique for transmitting a packet having in a header field thereof a checksum storage area after dividing the packet into multiple fragments.

2. Description of the Related Art

In transmission and reception of network data, heretofore, error-detecting codes have been added to the data so as to detect the occurrence of data errors. Transmission Control Protocol (TCP) and User Datagram Protocol (UDP), which are commonly-used protocols based on such an error detection scheme, have been standardized as RFC793 and RFC768, respectively, by the Internet Engineering Task Force (IETF, http://www.ietf.org/). There is a checksum field in the packet format of these protocols; thus, errors can be detected by a receiver through verification of a checksum having been attached to the data by a sender.

FIG. 6 illustrates the TCP packet format, and FIG. 7 illustrates the UDP packet format. In these formats as shown in FIGS. 6 and 7, various control information pieces required for communication are stored in a header field, and data to be transmitted is located following the header field. One of the control information pieces stored in the header field is a 16-bit checksum field. This checksum field takes 0 as an initial value, and takes a value obtained by adding all the data pieces, including data pieces in a field called a pseudo-header, carried in a packet at a time of data transmission. The checksum field value is calculated by use of an end-around carry, in which a carried value from the most significant bit is added into the least significant bit, so that the resultant value is always of 16 bits.

In the background of the time when these protocols described above were standardized, protocols were designed on the premise that they should be implemented by software installed in a minicomputer, and calculation of checksum which is one kind of error-detecting code also used to be performed by software. This is probably because the network communication speed is so slow at that time when these protocols were invented that software processing was enough to perform required processing for the network communication.

However, in the recent situation where high-speed network communications have been made available by the development of an optical communications technology and the like, all the required processing can no longer be completed by use of software alone, and therefore it has become necessary to perform processing by means of hardware. Being performed on all the data pieces in a packet, the checksum calculation used by these protocols imposes a large computational load on high-speed communication processing. Such a situation has given rise to a need to perform the checksum calculation by use of hardware.

In the meantime, the IETF describes several methods for checksum calculation for the Internet. The only method in which checksum calculation is performed by hardware is disclosed in “Implementing the Internet Checksum in Hardware” by J. Touch and B. Parham, IETF, rfc1936, April 1996 (Non-Patent Document 1). In this document, an actual checksum circuit based on a programmable logic device (PLD) is described. This checksum circuit is mounted as hardware used in direct memory access (DMA), to perform high-speed checksum calculation on hardware through pipeline and parallel processing.

The Non-Patent Document 1, however, failed to describe concrete configurations including writing in the header storage area and transmission operation, although the method was based on the premise of potential application of the checksum to the TCP and UDP packets. In an actual operation, it is difficult to successfully perform both DMA transfer and transmission concurrently, since a checksum storage area is located in a header field in the packet. Accordingly, it is necessary to read all the data pieces from the memory by a DMA transfer in order to perform checksum calculation, store a checksum value obtained in the checksum calculation in the checksum storage area in the header field, and then again read the packet data pieces stored in the memory for transmission.

Next, a description will be given of a configuration of a conventional packet transmission device. FIG. 8 is a schematic drawing illustrating memory access operations in a conventional packet transmission device. The packet transmission device in the drawing includes: a memory 101 for storing packets; a pointer 105 for indicating a position where a packet data is to be read; and a checksum calculation section 102 for calculating a checksum of the data set read from the memory 101. The checksum calculation section 102 includes a checksum calculation circuit 106 and a calculation result holding circuit 107. FIG. 8 illustrates an example of a packet divided into three fragments. A first fragment is composed of a data set 101b of a packet header and a data set 101c of a first fragment packet (first fragment packet data set). A second fragment is composed of a data set 101d following the first fragment packet data set 101c. A last fragment is composed of a last fragment packet data set 101e. Furthermore, in the memory 101, a data set 101a of a pseudo-header is located in front of the packet header data set 101b.

Next, a description will be given of an operation of packet transmission. FIG. 8 shows, on the left side, the movement order of the pointer 105 for pointing the memory 101. The pointer 105 is controlled to move in the following order of the data sets and from the beginning to the end in each of the data sets: a data set 101a; a data set 101b; a data set 101c; a data set 101d; a data set 101e; a data set 101b; a data set 101c; a data set 101d; and a data set 101e. It should be noted that an access operation is performed for writing into the checksum storage area (checksum field) located in the data set 101b between the accesses to the data sets 101e and 101b.

FIG. 9 is a flowchart illustrating operations of a conventional packet transmission device. Note that, the circled numbers 1 to 8 shown in FIG. 8 respectively correspond to the circled numbers 1 to 8 shown in the flowchart in FIG. 9.

Packet transmission is initiated in step S100 in FIG. 9.

In step S101, the pseudo-header data set 101a is created and read from the memory 101, and then sent to the checksum calculation circuit 106 for checksum calculation. It should be noted that the pseudo-header data set 101a is only used in the checksum calculation circuit 106 and not processed as transmission data.

Next, packet data sets 101b, 101c, 101d, and 101e including the header to be transmitted are sequentially read out. These read data sets are then sent to the checksum calculation circuit 106 and used for checksum calculation. Further, a final checksum result is stored in the calculation result holding circuit 107.

In step S103, the pointer 105 is moved to a position in the header in which the checksum result is to be stored (checksum field), and thereby the checksum calculation result is stored, in the checksum field.

Instep S104, the pointer 105 is moved to the front position of the packet (the front position of the data set 101b) in order to transmit the fragment including the header area in which the checksum calculation result is stored.

In step S105, the data sets 101b, 101c, 101d, and 101e are sequentially read from the memory 101 and transmitted while incrementing the pointer 105.

Steps S106 and S107 are repeatedly executed until a last fragment is read out and transmitted.

In step S108, if there is a packet to be transmitted on the completion of the transmission of the fragments, the pointer 105 is moved to the next packet storage region. If there is no packet to be transmitted, the series of operations are terminated.

A conventional packet transmission device transmits a packet having in a header field thereof a checksum storage area after dividing the packet into multiple fragments, in a manner described above.

As a related technique, Japanese Patent Application Publication No. 2000-253054 discloses a method for achieving higher-speed checksum calculation during packet generation and achieving higher-speed packet generation, even in the case where a packet transmission unit may vary for each data transmission.

### SUMMARY OF THE INVENTION

As shown in FIGS. 6 and 7, the checksum storage area is located in the header field of the TCP and UDP packets. In such a configuration, in the case where all the data sets located from the front to the end, as in the order of transmission, in the packet are to be processed, the checksum calculation is first completed from the beginning data set to the last data set, and then the checksum result is written into the header field which is located at the front of the packet by moving the pointer back to the header field. Accordingly, two memory accesses in total are required to all the data sets: one for checksum calculation by using the data sets and another for transmission of the data sets. This results in making the whole operation time-consuming. Furthermore, all the data sets corresponding to a packet have to be held until the operation is completed for the packet; thus, the efficiency of memory usage is low, so that a large free memory space is needed.

A packet transmission device according to a first aspect of the present invention transmits a packet having in a header thereof a checksum storage area after dividing the packet into multiple fragments. The packet transmission device includes: a memory section for storing packet data sets; a checksum calculation section; a transmission section; and a control section. In the checksum calculation section, data sets respectively corresponding to all the multiple fragments except for a fragment having the checksum storage area therein are read from the memory section, the read data sets are sequentially and cumulatively added to obtain a checksum value, and a data set corresponding to the fragment having the checksum storage area therein is read from the memory section and added to the checksum value to obtain a final checksum value. The transmission section sequentially transmits the fragments having been read from the memory section once the individual fragments are used for the checksum calculation in the checksum calculation section, and, after all the fragments have been transmitted, transmits the fragment having been read from the memory section and having therein the checksum storage area in which the final checksum value has been stored. The control section performs control such that the packet data sets can be read from the memory section, and provided to the checksum calculation section and the transmission section.

A packet transmission method according to a second aspect of the present invention is a method for transmitting a packet having in a header thereof a checksum storage area after dividing the packet into multiple fragments. The packet transmission method has the following two steps. In the first step, while a checksum value is calculated by sequentially and cumulatively adding data sets respectively corresponding to all the multiple fragments except for a fragment having the checksum storage area therein, the fragments are sequentially transmitted once the individual fragments are used for the checksum calculation. In the second step, a final checksum value which is obtained by adding to the checksum value a data set corresponding to the fragment having the checksum storage area therein is stored in the checksum storage area, and then the fragment having the checksum storage area therein is transmitted.

A packet transmission method according to a third aspect of the present invention is a method by using a network protocol for transmitting and receiving a packet having in a header thereof a checksum storage region after dividing the packet into multiple fragments. The method is configured to calculate a checksum value by sequentially and cumulatively adding data sets respectively corresponding to all the multiple fragments except for a fragment having the checksum storage area therein, to sequentially transmit fragments once the individual fragments are used for the checksum calculation, to store in the checksum storage area a final checksum value, which is obtained by adding to the checksum value the data set corresponding to the fragment having the checksum storage area therein after the transmission of all the fragments, and then to transmit the fragment having the checksum storage area therein.

In a configuration according to the present invention, on transmission of a packet having been divided into multiple fragments, each of the second to last fragments is read only once from the memory, and then the read fragment is transmitted while checksum is calculated. As a result, processing time required to complete the packet transmission can be shortened. Furthermore, memory space becomes available in a shorter period of time; thus, it is possible to make a large free memory space in the system.

### BRIEF DESCRIPTION OF THE DRAWING

FIG. 1 is a block diagram illustrating a configuration of a packet transmission device according to an embodiment of the present invention.

FIG. 2 is a schematic drawing illustrating memory access operations in a packet transmission device according to a first example of the present invention.

FIG. 3 is a flowchart illustrating operations of the packet transmission device according to the first example of the present invention.

FIG. 4 is a schematic drawing illustrating memory access operations in a packet transmission device according to a second example of the present invention.

FIG. 5 is a flowchart illustrating operations of the packet transmission device according to the second example of the present invention.

FIG. 6 is a drawing illustrating a format of a TCP packet.

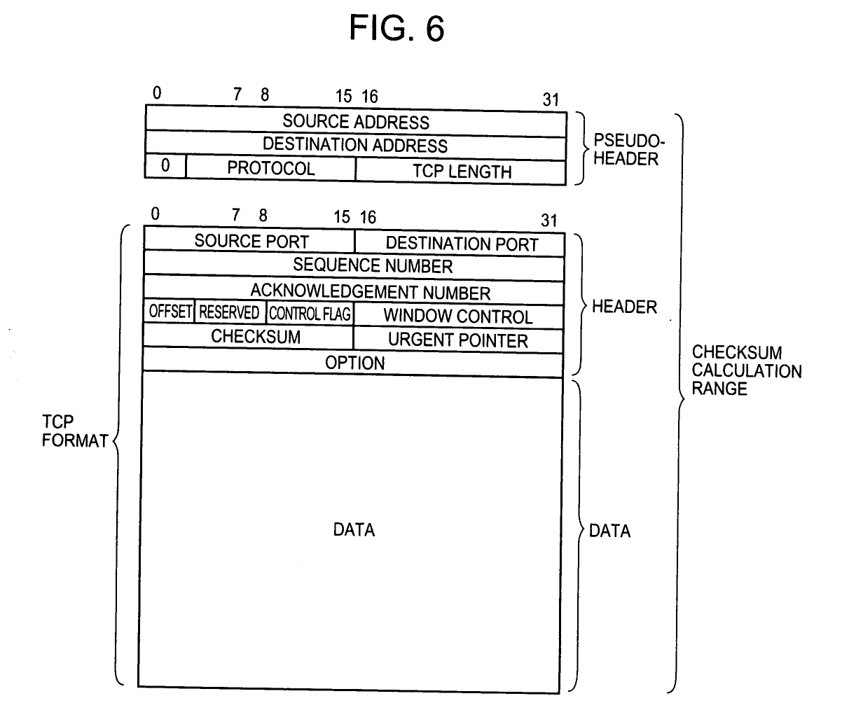

FIG. 7 is a drawing illustrating a format of a UDP packet.

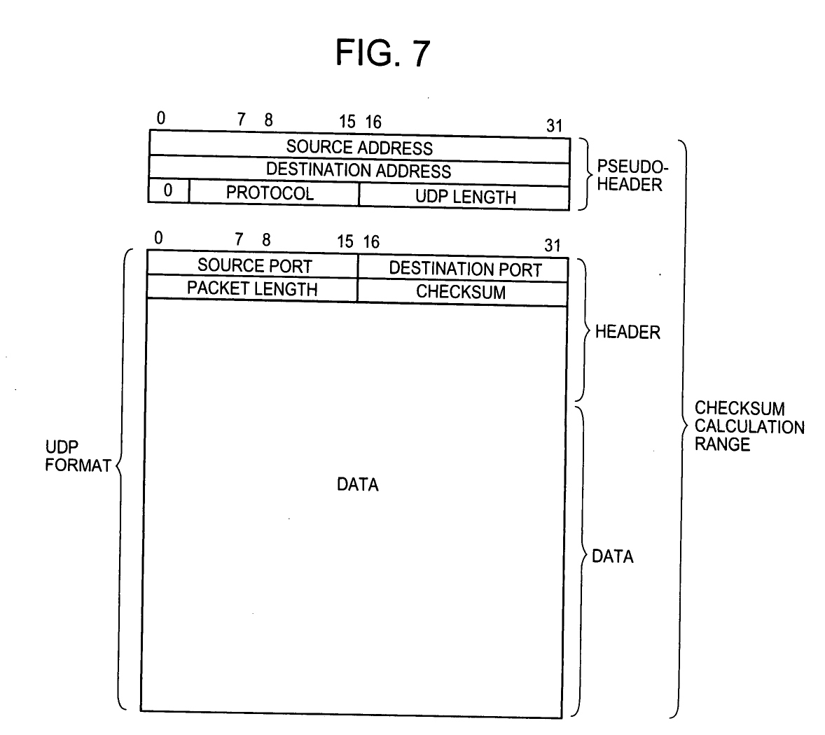

FIG. 8 is a schematic drawing illustrating memory access operations in a conventional packet transmission device.

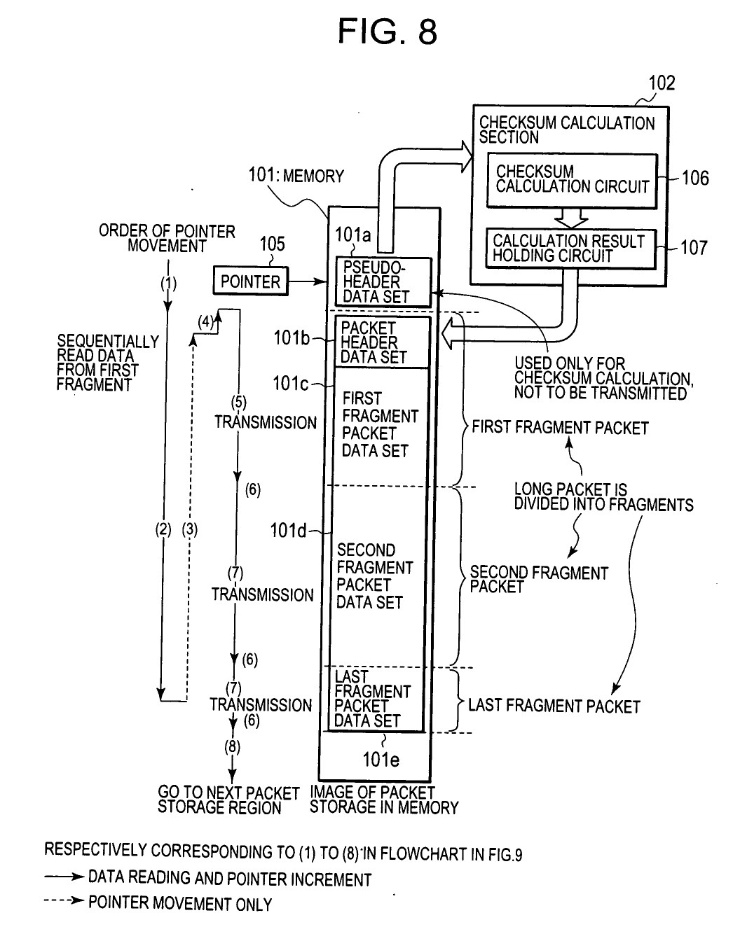

FIG. 9 is a flowchart illustrating operations of the conventional packet transmission device.

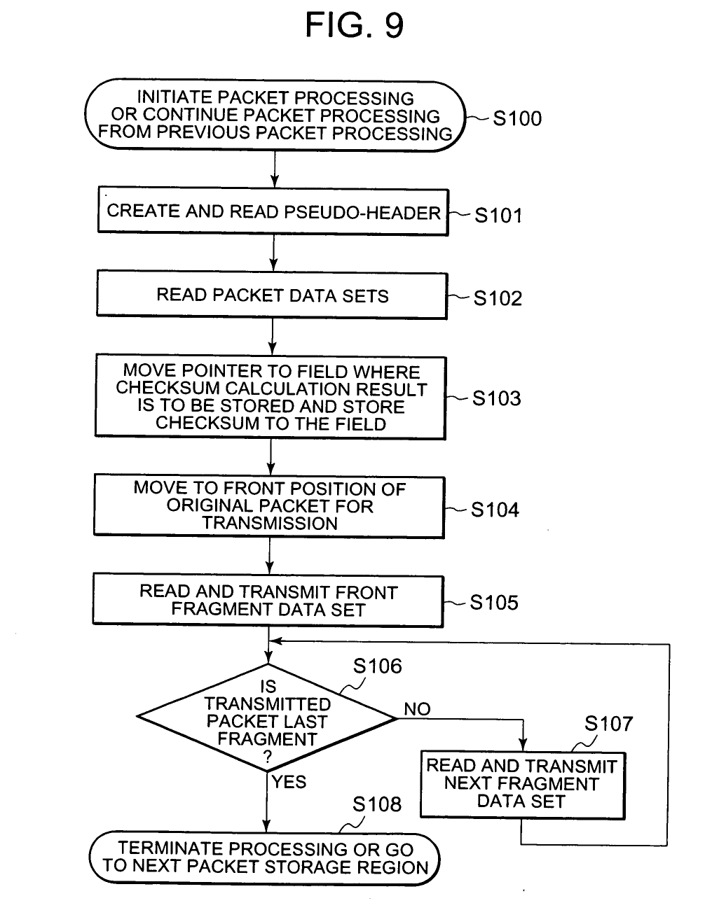

### DESCRIPTION OF THE PREFERRED EMBODIMENT

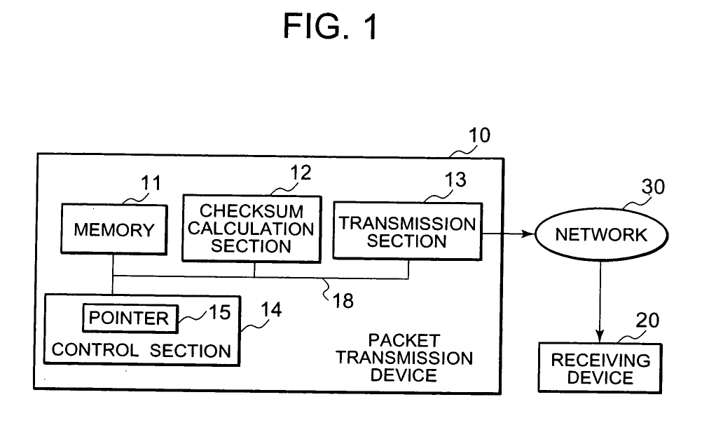

FIG. 1 is a block diagram illustrating a configuration of a packet transmission device according to an embodiment of the present invention. In FIG. 1, a packet transmission device 10 divides a packet having in a header field thereof a checksum storage area into multiple fragments, and then transmits the multiple fragments to a receiving device 20 via a network 30. The packet transmission device 10 includes a memory 11, a checksum calculation section 12, a transmission section 13, a control section 14, and a connecting line 18.

The connecting line 18 in this embodiment establishes connections among the memory 11, the checksum calculation section 12, the transmission section 13, and the control section 14, allowing them to exchange data and control signals thereamong. The connecting line 18 may also have a bus structure. Through the exchange of data and control signals, processing described in the following section is executed in the packet transmission device 10.

Incidentally, the checksum calculation section 12 and the control section 14 may be configured of a dedicated control circuit composed of a state machine, a sequencer and the like. It may also be configured that read and write of data from and to the memory 11, checksum calculation, pointer control, and the like are performed by use of a processor or the like which executes a program (software).

Data of a packet to be transmitted is stored in advance in the memory 11.

The checksum calculation section 12 reads data sets respectively corresponding to all the multiple fragments except for a fragment having a checksum storage area therein from the memory 11, and calculates a checksum value by sequentially and cumulatively adding the read data sets. Then, a data set corresponding to the fragment having the checksum storage area therein is read from the memory 11, and added to the checksum value to obtain a final checksum value.

The transmission section 13 sequentially transmits the fragments read from the memory 11, except for the fragment having the checksum storage area therein, once the individual fragments are used for the checksum calculation in the checksum calculation section 12. After all the above-mentioned fragments have been transmitted, the transmission section 13 transmits the fragment which has been read from the memory 11 and has the checksum storage area in which the final checksum value is stored.

The control section 14 has a pointer 15, which indicates an access position (address) in the memory 11, and updates the contents of the pointer 15 so as to control the checksum calculation section 12. To be more specific, the control section 14 controls by use of the pointer 15 so that packet data can be read from the memory 11 and provided to the checksum calculation section 12 and the transmission section 13. For such control of the control section 14 over the checksum calculation section 12, it may also be configured that a pseudo-header is created after the transmission section 14 has sequentially transmitted the fragments, and the pseudo-header is written in the memory 11 so as to be used for the cumulative addition to obtain a checksum value. Likewise, it may also be configured that a pseudo-header is created in advance and written in the memory 11 so as to be used as an initial value for the cumulative addition to obtain a checksum value.

In this case, the checksum calculation performed in the checksum calculation section 12 is a simple addition, and therefore a resultant checksum value would be the same at the end after all the values have been added, no matter from which fragment the calculation may be started within a packet. In the case of transmitting a packet having a large data amount, the packet transmission device 10 divides the packet into multiple fragments prior to the transmission. In such transmission, it is controlled by the packet transmission device 10 that: the checksum calculation section 12 performs checksum calculation from a second fragment packet; the transmission section 13 sequentially transmits the fragments once they are used for the calculation; the checksum value in a front fragment is calculated after all the fragments have been transmitted; and the calculated checksum value is transmitted. With the above controls, both checksum calculation and transmission can be performed by reading the packet data only once from the memory. In this processing, not only the processing time can be shortened, but also the efficiency of memory usage can be improved by deallocating used memory space to make it available for other packet processing.

It should be noted that fragments of a packet are not necessarily received by the receiving device 20 in a correct order because the routing of the fragment packets are determined on a packet basis during transfer. However, the receiving device 20 performs reassembly of fragmented packets as a part of its regular operation; thus, there will be no problem even if fragment packets are transmitted in a different order (a front fragment packet is transmitted at the end) Since it is normally expected that fragments of the receiving device 20 may arrive via multiple routes in the network 30, the receiving device 20 has a function for reassembling packet fragments in a correct order. Since such a function of the receiving device 20 is available, the order of fragments to be received by the receiving device 20 can be configured as described. In the following section, a detailed description will be given of the embodiment of the present invention by referring to Examples.

### EXAMPLE 1

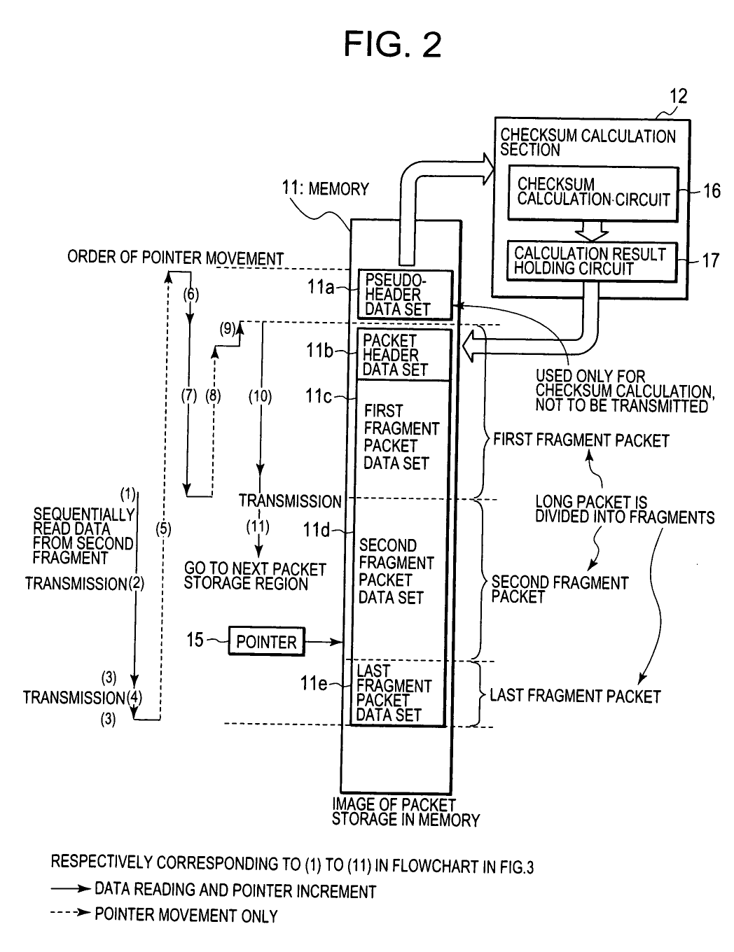

FIG. 2 is a schematic drawing illustrating memory access operations in the packet transmission device according to a first example of the present invention. The checksum calculation section 12 includes: a checksum calculation circuit 16 for calculating checksum of data read from the memory 11; and a calculation result holding circuit 17 for holding a checksum calculation result.

FIG. 2 shows an example of a packet divided into 3 fragments. A first fragment is composed of a data set 11b of a packet header and a data set 11c of a front fragment packet which follows the packet header. A second fragment is composed of a data set 11d which follows the front data set 11c. A third fragment is composed of a data set lie of a last fragment packet data. In this example, the fragment is divided into three fragments; however, the number of packet fragments may vary depending on packet length.

Next, a description will be given of an operation of the packet transmission device. On the left side of FIG. 2, the order of the movement of the pointer 15 for pointing the memory 11 is shown. The movement of the pointer 15 is controlled to move in the following order of the data sets from the beginning to the end of each of the data sets: a data set 11d; a data set 11e; a data set 11a of a pseudo-header; a data set 11b; a data set 11c; a data set 11b; and a data set 11c. It should be noted that an access operation is performed for writing into a checksum storage area (checksum field) in the data set 11b between the accesses to the data sets 11c and 11b.

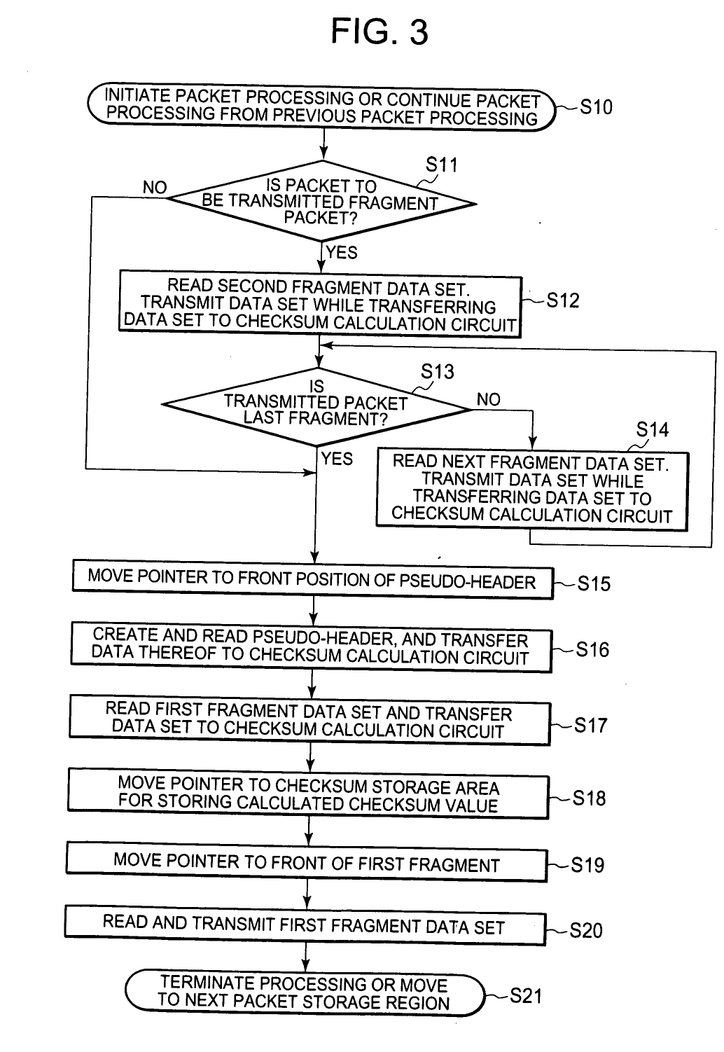

FIG. 3 is a flowchart illustrating operations of the packet transmission device according to the first example of the present invention. Note that, the circled numbers 1 to 11 shown in FIG. 2 respectively correspond to the circled numbers 1 to 11 shown in the flowchart in FIG. 3.

Packet transmission is initiated in step S10.

In step S11, it is determined whether or not a packet to be transmitted is a fragment packet, that is, a packet to be divided into fragments for transmission. If a packet is not to be divided into fragments, the operation proceeds to step S15. If a packet is to be divided into fragments, the operation proceeds to step S12.

In step S12, the pointer 15 is moved to the position of the second fragment packet data (the position of the data set 11d), and the second fragment packet data set is read out. The read data set is transferred to the checksum calculation circuit 16 to be used for checksum calculation. As the checksum calculation is being performed, the read data set is transmitted as transmit data.

In step S13, it is determined whether or not the transmitted fragment is a last fragment packet. If not, the next fragment packet data is read out in step S14. The data set thus read is transferred to the checksum calculation circuit 16 to be used for checksum calculation. During the checksum calculation, the data set is transmitted as transmit data. Steps S13 and S14 are repeatedly executed until the processing on the data set of the last fragment packet is completed.

After the processing of the data set of the last packet fragment, the pointer 15 is moved in step S15 to the position of the pseudo-header in the memory 11 (the position of the data set 11a).

In step S16, a data set 11a of the pseudo-header read from the memory 11 is transferred to the checksum calculation circuit 16 to be used for checksum calculation. It should be noted that the pseudo-header data set 11a is only used in the checksum calculation circuit 16 and not processed as transmit data.

In step S17, data sets 11b and 11c constituting the first fragment packet including the header to be transmitted are read out, and transferred to the checksum calculation circuit 16 to be used for checksum calculation. A final result of checksum calculation is stored in the calculation result holding circuit 17.

In step S18, the pointer 15 is moved to the position of the header in which the result of checksum calculation is to be stored (checksum field), and thereby the result of checksum calculation is stored in a header field.

In step S19, the pointer 15 is moved to the front position of the packet so as to transmit the fragment having the header field in which the checksum calculation result is stored.

In step S20, the packet data sets (data sets 11b and 11c) are sequentially read from the memory 11 and transmitted while incrementing the pointer 15. After the completion of the transmission, in step S21, if there is a packet to be transmitted next, the pointer 15 is moved to the next packet storage region. If there is no packet to be transmitted, the series of operations are terminated.

In the packet transmission device configured to operate as described above, checksum calculation for packet data is initiated from the second fragment packet. The packet transmission device in this example is configured to read data sets respectively corresponding to the second to last fragments only once from the memory 11, and the read data sets are transmitted while checksum is calculated; thus, redundant memory access can be avoided. Furthermore, the packet transmission device is capable of transmitting data sets promptly after the individual data sets are used for checksum calculation, and therefore memory space in the memory 11 holding data can be cleared after the transmission. Hence, it is possible to reduce the number of times data sets are read from the memory 11, and thereby to improve the efficiency in processing time and memory region.

### EXAMPLE 2

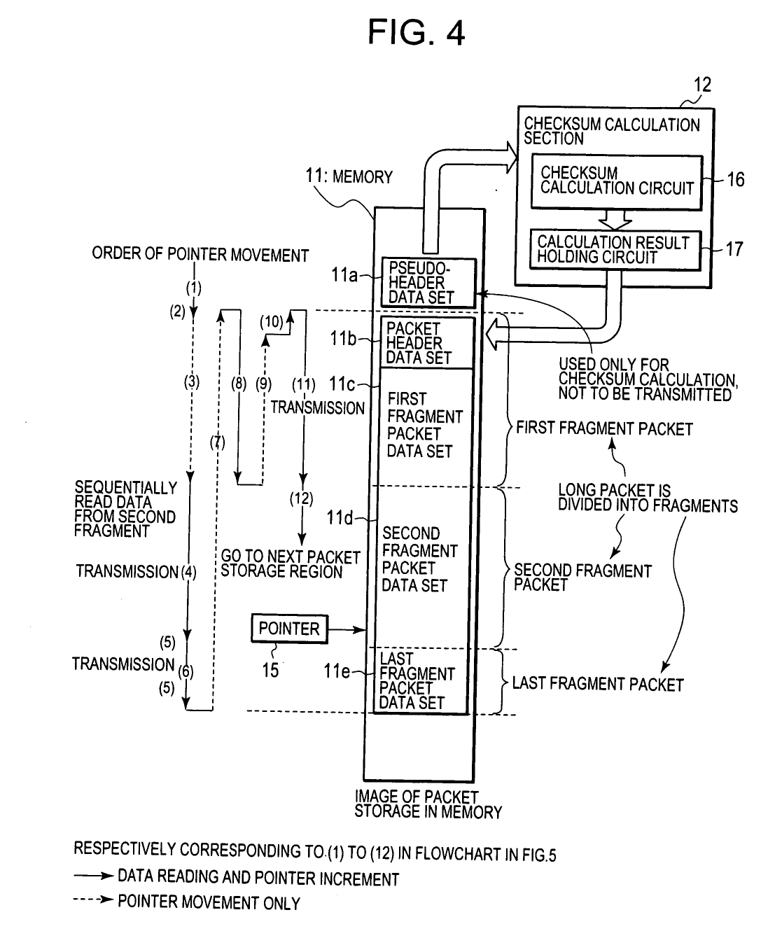

FIG. 4 is a schematic drawing illustrating memory access operations in a packet transmission device according to a second example of the present invention. Since the configuration of the packet transmission device is the same as that illustrated in FIG. 1, no further description will be given of the configuration. The arrangement of data in the memory 11 illustrated in FIG. 4 is the same as that in FIG. 2, and therefore no further description will be given of the data arrangement. The difference of the packet transmission device of the second example from that of the first example is the order of access to the data stored in the memory 11, which is, in particularly, the order of access to the data set 11a of the pseudo-header.

On the left side of the FIG. 4, the order of the movement of the pointer 15 is shown. The pointer 15 is controlled to move in the following order of the data sets from the beginning to the end of each of the data sets: a data set 11a of the pseudo-header; a data set 11d; a data set 11e; a data set 11b; a data set 11c; a data set 11b; and a data set 11c. In other words, prior to the accesses to a series of packet data sets, the pseudo-header data set 11a is accessed. It should be noted that an access operation is performed for writing into the checksum storage area (checksum field) in the data set 11b between the accesses to the data sets 11c and 11b.

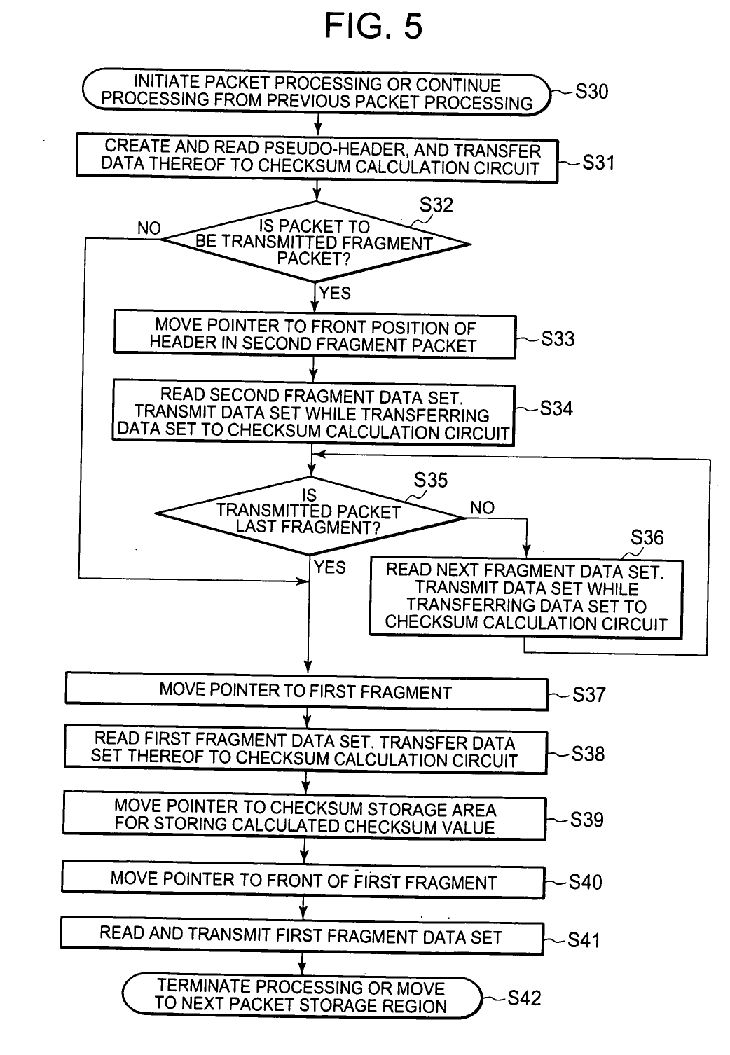

Next, a description will be given of operations of the packet transmission device. FIG. 5 is a flowchart illustrating an operation of the packet transmission device according to the second example of the present invention. Note that, the circled numbers 1 to 12 shown in FIG. 4 respectively correspond to the circled numbers 1 to 12 shown in the flowchart in FIG. 5.

Packet transmission is initiated in step S30.

In step S31, the pointer 15 is moved to the position of the pseudo-header in the memory 11. The pseudo-header is created and read from the memory, and then the read data set 11a of the pseudo-header is transferred to the checksum calculation circuit 16 to be used for checksum calculation. It should be noted that the pseudo-header data set 11a is only used in the checksum calculation circuit 16 and not processed as transmit data.

In step S32, it is determined whether or not t packet to be transmitted is a fragment packet, that is, a packet to be divided into fragments for transmission. If a packet is not to be divided into fragments, the operation proceeds to step S37. If a packet is to be divided into fragments, the operation proceeds to step S33.

In step S33, the pointer 15 is moved to the position of the second fragment packet data (the position of the data set 11d).

In step S34, the second fragment packet data set 11d is read out. The read data set 11d is transferred to the checksum calculation circuit 16 to be used for checksum calculation. As the checksum calculation is being performed, the read data set is transmitted as transmit data.

In step S35, it is determined whether or not the transmitted fragment packet is the last one. If not, the next fragment packet data is read out in step S36. The data set thus read is transferred to the checksum calculation circuit 16 to be used for checksum calculation. As the checksum calculation is being performed, the read data set is transmitted as transmit data. Steps S35 and S36 are repeatedly executed until the processing on the data set of the last fragment packet is completed.

After the processing of the data set of the last fragment has been completed, the pointer 15 is moved in step S37 to the position of the first fragment packet.

In step S38, data sets 11b and 11c constituting the first fragment packet including the header to be transmitted are read out, and are transferred to the checksum calculation circuit 16 to be used for checksum calculation. A final result of checksum calculation is stored in the calculation result holding circuit 17.

In step S39, the pointer 15 is moved to the position of the header in which the result of checksum calculation is to be stored, and thereby the result of checksum calculation is stored in the checksum storage area (checksum field) in a header field.

In step 40, the pointer 15 is moved to the front position of the packet so as to transmit the fragment having the header field in which the checksum calculation result is stored.

In step S41, the packet data sets (data sets 11b and 11c) are sequentially read from the memory 11 and transmitted while incrementing the pointer 15. After the completion of the transmission, in step S42, if there is a packet to be transmitted next, the pointer 15 is moved to the next packet storage region. If there is no packet to be transmitted, the series of processing are terminated.

In the packet transmission device configured to operate as described above, the pseudo-header is created and read out before checksum calculation of the second fragment packet is performed. In this way, without changing the process that the checksum calculation is initiated from the second fragment packet as described above, calculation may be performed on the pseudo-header data set before the packet data sets.

The present invention has been described by referring to the examples above. However, the present invention is not to be limited to the above-described examples. Hence, it is natural that the present invention accordingly include various modifications and corrections, which are possibly achieved by those skilled in the art, within the scope of the claims of the present invention.

What is claimed is:

1. A packet transmission device for transmitting a packet having in a header thereof a checksum storage area after dividing the packet into a plurality of fragments, comprising:
a memory section for storing data of the packet;
a checksum calculation section for reading from the memory section data sets respectively corresponding to all the plurality of fragments except for a fragment having the checksum storage area therein, for sequentially and cumulatively adding the data sets to obtain a checksum value, for reading a data set of the fragment having the checksum storage area therein from the memory section, and for adding the read data set to the checksum value to obtain a final checksum value;
a transmission section for sequentially transmitting the individual fragments having been read from the memory section once the fragments are used for the checksum calculation in the checksum calculation section, and for transmitting, after all the fragments except for the one have been transmitted, the fragment having been read from the memory section and having therein the checksum storage area in which the final checksum value is stored; and
a control section for performing control to read the data of the packet from the memory section and to provide the read data to the checksum calculation section and the transmission section.

2. The packet transmission device according to claim 1, wherein
after the sequential transmission of the fragments by the transmission section, the control section controls the checksum calculation section by creating a pseudo-header and writing the pseudo-header in the memory section so that the checksum calculation section can perform on the pseudo-header the cumulative addition to obtain the checksum value.

3. The packet transmission device according to claim 1, wherein
the control section controls the checksum calculation section by creating a pseudo-header in advance and writing the pseudo-header in the memory section so that the checksum calculation section can use the pseudo-header as an initial value for the cumulative addition to obtain the checksum value.

4. The packet transmission device according to claim 2, wherein
the control section is provided with a pointer for indicating an access position in the memory section, and updates the pointer so as to control access to data to be calculated by the checksum calculation section and data to be transmitted by the transmission section.

5. The packet transmission device according to claim 3, wherein
the control section is provided with a pointer for indicating an access position in the memory section, and updates the pointer so as to control access to data to be calculated by the checksum calculation section and data to be transmitted by the transmission section.

6. A packet transmission method for transmitting a packet having in a header thereof a checksum storage area after dividing the packet into a plurality of fragments, comprising the steps of:
calculating a checksum value by sequentially and cumulatively adding data sets respectively corresponding to all the plurality of fragments except for a fragment having the checksum storage area therein, while sequentially transmitting the fragments once the individual fragments are used to obtain the checksum value; and
storing in the checksum storage area a final checksum value obtained by adding to the checksum value a data set corresponding to the fragment having the checksum storage area therein, and then transmitting the fragment having the checksum storage area therein.

7. The packet transmission method according to claim 6, further comprising the step of:
creating a pseudo-header between the step of sequentially transmitting the fragments and the step of transmitting the fragment having the checksum storage area therein, wherein
the cumulative addition to obtain the checksum value is performed on the pseudo-header.

8. The packet transmission method according to claim 6, further comprising the step of:
creating in advance a pseudo-header before data sets respectively corresponding to all the plurality of fragments except for the fragment having the checksum storage area therein are sequentially and cumulatively added, wherein
the pseudo-header is used as an initial value for the cumulative addition to obtain the checksum value.

9. A packet transmission method by using a network protocol for transmitting and receiving a packet having in a header thereof a checksum storage region after dividing the packet into a plurality of fragments, comprising the steps of:
calculating a checksum value by sequentially and cumulatively adding data sets respectively corresponding to all the plurality of fragments except for a fragment having the checksum storage area therein;
sequentially transmitting the fragments except for the one once the individual fragments are used for the checksum calculation;
obtaining a final checksum value by adding to the checksum value the data set corresponding to the fragment having the checksum storage area therein after the transmission of all the fragments except for the one;
storing the obtained final checksum value in the checksum storage area; and
transmitting the fragment having the checksum storage area therein.
